(19) United States
(12) Patent Application Publication
(10) Pub. No.: US 2026/0238031 A1
(43) Pub. Date: Aug. 13, 2026

(54) METHOD FOR CHARGING A RECHARGEABLE ENERGY STORAGE DEVICE, CHARGER, AND CHARGING SYSTEM

(71) Applicant: Sivantos Pte. Ltd., Singapore (SG)

(72) Inventors: Kim Hui TOO, Singapore (SG); Kin Khan CHOE, Singapore (SG); Heng Goh YAP, Singapore (SG)

(21) Appl. No.: 19/464,916

(22) Filed: Jan. 30, 2026

(30) Foreign Application Priority Data
Feb. 11, 2025 (DE) 10 2025 105 032.5

(51) Int. Cl. H02J 7/90; G01R 31/382; H02J 7/70; H02J 7/82; H02J 7/94; H04R 1/1025

(52) U.S. Cl. CPC H02J 7/933; G01R 31/382; H02J 7/751; H02J 7/82; H02J 7/94; H04R 1/1025; H02J 2207/20

(57) ABSTRACT

A method and a charger for charging a rechargeable energy storage device of an electronic device via a charging interface. A stored charging voltage is applied to the charging interface at the beginning of a charging operation. A resulting charging current flowing through the charging interface is detected during the charging operation and a current state of charge of the energy storage device is determined based on the detected charging current. A voltage level for the charging voltage is determined for the specific state of charge, and the charging voltage is set to the determined voltage level.

### CROSS-REFERENCE TO RELATED APPLICATION

This application claims the priority, under 35 U.S.C. § 119, of German Patent Application DE 10 2025 105 032.5, filed Feb. 11, 2025; the prior application is herewith incorporated by reference in its entirety.

### FIELD AND BACKGROUND OF THE INVENTION

The invention relates to a method for charging a rechargeable energy storage device of an electronic device via a charging interface. The invention further relates to a charger for carrying out the method and to a charging system with such a charger.

A hearing device is generally defined as an electronic device which supports the hearing of a person wearing the hearing device. In particular, the invention relates to a hearing device which is designed to fully or partially compensate for a hearing loss of a hearing-impaired user. Besides such hearing aids (HA), there exist devices which protect or improve the hearing of users with normal hearing, for example by enabling improved speech comprehension in complex listening situations. Such hearing device devices are also known as “Personal Sound Amplification Products” (PSAP for short). Finally, the term “hearing device” as used here also includes headphones worn on or in the ear (wired or wireless, with or without active noise cancellation), headsets, etc., as well as implantable hearing devices, such as cochlear implants. A hearing device can also be part of an AR system (AR: Augmented Reality) or VR system (VR: Virtual Reality) for outputting the acoustic information of a virtual sound source to the user.

Hearing devices in general, and personal sound amplification products in particular, are usually designed to be worn on the head and in particular in or on an ear of the user, particularly as behind-the-ear devices (also known as BTE devices) or in-the-ear devices (also known as ITE devices). With regard to their internal structure, hearing devices generally have at least one output converter which converts an outputted audio signal supplied for the purpose of output into a signal that is perceptible to the user as sound and outputs the latter to the user.

In most cases, the output transducer is embodied as an electro-acoustic transducer which converts the (electrical) audio output signal into airborne sound, this outputted airborne sound being emitted into the user's auditory canal. In a hearing device that is worn behind the ear, the output transducer, also known as the receiver, is usually integrated outside the ear in a housing of the hearing device. In this case, the sound emitted by the output transducer is directed into the user's auditory canal via a sound tube. Alternatively, the output transducer can also be located in the auditory canal and thus outside the housing worn behind the ear. Such hearing devices are also called receiver-in-canal or RIC devices. Hearing devices that are worn in the ear and are so small that they do not protrude beyond the auditory canal are also called CIC (completely-in-canal) devices.

In other designs, the output transducer can also be embodied as an electro-mechanical transducer that converts the audio output signal into structure-borne sound (vibrations), this structure-borne sound being emitted, for example, into the user's cranial bone. Furthermore, there are implantable hearing devices, particularly cochlear implants, and hearing devices whose output transducers directly stimulate the user's auditory nerve.

In addition to the output transducer, a hearing device often has at least one (acousto-electrical) input transducer. During operation of the hearing aid, the or each of the input transducers receives airborne sound from the environment of the hearing device and converts this airborne sound into an audio input signal (i.e., an electrical signal that carries information about the ambient sound). This audio input signal—also referred to as the “received sound signal”—is normally outputted to the user in its original or processed form, for example in order to implement a so-called transparency mode in headphones, for active noise suppression, or—in a personal sound amplification product, for example—to improve the user's sound perception.

In addition, a hearing device often has a signal processing unit (signal processor). It is in the signal processing unit that the audio input signal(s) are processed (i.e., modified with respect to their sound information). The signal processing unit outputs an appropriately processed audio signal (also referred to as “audio output signal” or “modified sound signal”) to the output converter and/or to an external device.

Hearing devices are usually powered by batteries as an internal energy store. The operating time is limited depending on the energy content (energy charge) of the batteries and the requirements of the hearing device (particularly the energy consumption thereof). Given the general trend toward miniaturization, smaller batteries are preferred, which further limits their energy content. To avoid the frequent replacement of used batteries, hearing devices can be powered by rechargeable batteries (accumulators) such as nickel-metal hydride (NiMH) or lithium-ion (Li-ion) batteries.

Hearing devices that are powered by rechargeable batteries often have connections for establishing an electrical contact with a charger, thus enabling the rechargeable batteries to remain inside the hearing device while being recharged. During a charging operation, the highest possible charging efficiency is desired in order to reduce heat generation during the charging operation, to provide a more compact portable charger, and to increase the number of charging operations or charging cycles that a charger—particularly a portable one—can provide.

Improved charging efficiency can be achieved, for example, by supplying just enough charging current to charge the device's energy storage while minimizing power loss.

In a conventional charging method, for example, a constant charging voltage, such as 5 V (volts), is applied to a charging input of a charge controller of the device that is to be charged. The charge controller operates in a constant current mode and delivers a preset constant charging current to the energy storage device. From the charger's point of view, a slightly higher charging current is drawn than the battery charging current, with the additional current being used for the internal processes of the charge controller during the charging operation. As the charging operation progresses, the battery voltage gradually increases, because the constant charging current flows into the battery and the charge accumulates. If the charging voltage of the charger is significantly higher than the battery voltage of the energy storage device, particularly at the beginning of the charging operation, the total charging power exceeds the combined power required to charge the battery and operate the charge controller. The difference between the total charging power and the power used to charge the battery and operate the charge controller represents excess power, which is essentially wasted power that is often dissipated as heat in the charge controller instead of being used directly to charge the energy storage device.

Our commonly assigned patent application US 2024/0204570 A1 discloses a method for charging a rechargeable energy storage device of an electronic device with which increased charging efficiency is achieved. To achieve this, the charging voltage fed into the device is continuously adjusted to the battery voltage plus an offset. This ensures that the charging power is kept just high enough to charge the energy storage device while minimizing excess power. However, implementing that method requires a communication mechanism between the charger and the device being charged, such as load modulation or wireless communication, in order to transmit the battery voltage information to the charger. For example, the charger demodulates the received signal, decodes the battery voltage information, and then adjusts the charging voltage accordingly. Such continuous variation of the charging voltage makes it possible to reduce the heat output of the charge controller.

Unfortunately, only about 50% of the entertainment and hearing device electronics available on the market have a communication function between device and charger, particularly in contact charging scenarios. The lack of battery voltage information in the charger limits the implementation of the continuously varying charging voltage for most electronic devices, with the effect that those devices generally have a low charging efficiency.

### SUMMARY OF THE INVENTION

It is an object of the invention to provide an especially suitable method for charging a rechargeable energy storage device of an electronic device via a charging interface. It is a particular object to specify a charging method which achieves the highest possible charging efficiency without the need for a communication connection to the electronic device. It is also an object of the invention to provide an especially suitable charging device and an especially suitable charging system.

With the above and other objects in view there is provided, in accordance with the invention, a method for charging a rechargeable energy storage device of an electronic device via a charging interface, the method comprising:
at a beginning of a charging operation, applying a stored charging voltage to the charging interface;
detecting a charging current flowing through the charging interface during the charging operation;
determining a current state of charge of the energy storage device based on the detected charging current;
determining a specific voltage level for the charging voltage for the state of charge; and
setting the charging voltage to the determined specific voltage level.

The advantages and embodiments mentioned with regard to the method can also be applied analogously to the charging device and or charging system, as described, and vice versa.

The conjunction “and/or” is to be understood here and in the following such that the features linked by this conjunction can be realized both jointly and as alternatives to one another. A corresponding expression is “at least one of A or B,” which defines a choice of either A alone, B alone, or A and B together.

Wherever method steps are described below, advantageous embodiments of the charger and/or the charging system result in particular from the fact that it is (or they are) designed to carry out one or more of these method steps.

The method according to the invention is intended, suitable, and configured for charging a rechargeable energy storage device of an electronic device via a charging interface. The method is carried out in particular by a charger for the electronic device.

Here and in the following, “charging an energy storage device” refers in particular to the (re) charging of such an energy storage device with electrical energy.

In the following, a “rechargeable energy storage device” refers in particular to a secondary battery of the electronic device in which consumed energy can be restored by means of an electrical (re) charging operation. The energy storage device is embodied, for example, as an electrochemical battery, in particular a rechargeable battery—for example as a rechargeable lithium-ion battery.

The charging interface is embodied in particular as a charging contact or charging port (charging pin, charging plug, charging socket), so that a galvanic coupling to the electronic device is achieved in the course of the method. In other words, the electronic device has a complementary (mating) charging interface which is connected to the charging interface in order to feed the charging energy into the device or into the energy storage system. In other words, the energy storage device is charged by contact charging or as a contact charging scenario. Preferably, the electronic device has a charge controller between the charging interface and the energy storage device which monitors the charging operation on the device side.

The electronic device is, for example, entertainment or telecommunications electronics, in particular a hearing instrument. In this context, a hearing instrument is understood to be a device for outputting an audio signal such as speech or music, e.g., a telephone, smartphone, headset, headphones, earphones, or music player. Preferably, the hearing device is a personal sound amplification product, i.e., an electronic device which, during operation, supports the hearing of the wearer (i.e., of the user or wearer of the hearing device). The hearing device—in that case referred to as a hearing aid—is specifically designed to at least partially compensate for the hearing impairment of a hearing-impaired user. Other types of hearing instruments aim to support the hearing of users with normal hearing, i.e., to improve speech perception in complex acoustic situations.

According to the method, a stored charging voltage is applied to the charging interface at the beginning of a charging operation. In other words, a charging voltage with a defined (initial) voltage level, i.e., a constant nominal charging voltage, is generated. The voltage level of the charging voltage is dimensioned such that the charge controller of the electronic device begins to operate.

Subsequently, the electrical charging current flowing through the charging interface is detected during the charging operation. For this purpose, the charging interface is continuously monitored by a current sensor, for example.

The invention proceeds from the insight that a magnitude of the charging current (charging current amplitude or the charging current intensity) varies considerably depending on the state of charge of the device-side energy storage device, meaning that the charging current measured at the charging interface can be used to determine a current state of charge. Owing to a certain amount of power consumption in the charge controller, the charging current flowing via the charging interface is dimensioned somewhat higher than the charging current associated with the respective state of charge.

According to the invention, the current state of charge of the energy storage device is determined during the charging operation based on the detected or measured charging current. According to the invention, a (target) voltage level for the charging voltage is determined based on the specific state of charge, and then the charging voltage is set to this specific voltage level. In other words, the charging voltage is changed (adjusted) so that it corresponds to a voltage level that is appropriate for the current state of charge. A “suitable voltage level” in this context refers to a charging voltage that is higher than the output voltage of the energy storage device in its current state of charge in order to ensure an uninterrupted charging operation when the device switches between different states of charge. This results in an especially suitable method for charging a rechargeable energy storage device.

The method according to the invention controls and/or regulates the charging voltage based on a state of charge of the energy storage device derived from the charging current, thus making it possible to power loss and improve charging efficiency. In particular, the need for communication with the electronic device or charge controller thereof is eliminated, since the state of charge is derived from the measured charging current. This simplifies the design of a suitable charger and reduces the processing power requirements.

In other words, the charging voltage is adjusted from the charger to the device based on the magnitude of the charging current fed into the device via the charging interface without requiring any communication between the device and the charger. The method according to the invention essentially represents a refinement of the charging method of continuously varying charging voltage described in the above-mentioned US 2024/0204570 A1, thus improving the charging efficiency for electronic devices that do not have the capability to communicate with the charger.

In an advantageous refinement, the current state of charge is determined by comparing the detected charging current with a stored current threshold. In other words, at least one state of charge of the energy storage device is characterized by a corresponding charging current value, and the detected charging current is compared with at least one such stored charging current value in order to determine the current state of charge of the device, more particularly of the energy storage device.

Preferably, a certain tolerance range around the charging current value is taken into account when comparing threshold values. In other words, the state of charge of the energy storage device is associated with a charging current range or charging current interval, it being checked in the course of the threshold comparison whether the detected charging current is within this range or interval, i.e., whether the detected charging current is greater than a lower limit (charging current value minus tolerance value) and less than an upper limit (charging current value plus tolerance value).

The tolerance value is defined, for example, as a percentage of the charging current or as an absolute value that represents a fraction of the charging current.

The use of a percentage is generally preferred for high charging currents, e.g., in fast charging scenarios. On the other hand, the absolute value is generally used for low charging currents, such as those used for normal charging, recovery from deep discharge, and the termination of charging. The reason for using an absolute value for low charging currents is that the percentage tolerance for low charging currents has a narrower range compared to high charging currents. This narrower tolerance range can make it difficult for the charger to accurately determine the current state of charge, particularly if there are slight differences in charging currents between devices.

In a preferred embodiment, a number of current thresholds or threshold ranges for different states of charge are stored. In other words, a discrete number of states of charge are defined for the energy storage device.

In one conceivable application, for example, four states of charge for the energy storage device are defined and stored. The states of charge include, for example, “over-discharged battery recovery,” “fast charging,” “normal charging,” and “terminate charging operation.”

The following specifications refer in particular to an electronic device that is embodied as a hearing instrument or hearing device. The energy storage device is a lithium-ion battery, for example, which has an energy storage or battery voltage of between 4.2 V and 4.35 V when fully charged. However, the specifications can also be applied analogously to other electronic devices or voltage ranges.

The state of charge “over-discharged battery recovery” (ODBR) occurs when the energy storage voltage is below a normal operating range, for example below 3.0 V. The ODBR state of charge enables recovery after a deep discharge of the energy storage device. For example, it is conceivable that the electronic device might define a lower voltage threshold, e.g., below 2.5 V, for example due to the presence of a protection module between the energy storage device and the charge controller. In such a module, for example, a body diode connected in parallel to a transistor switch opens when the energy storage voltage falls below a normal operating range in order to prevent further discharge. The conduction of the body diode causes a voltage drop along the energy storage connection path, which allows the charge controller to detect that the energy storage is in an over-discharged state, at a lower voltage than usual for recovery.

The state of charge “fast charging” (FAST) occurs when the energy storage voltage is within a normal operating range but close to a lower end, for example between 3.0 V and 3.9 V. The FAST state of charge, or rather the charging operation during the FAST state of charge, is designed to provide the highest possible charging current in the shortest possible charging time. This allows for the longest possible usage time of the electronic device to be achieved within a short charging time. For example, a half-hour of fast charging will provide a usage time of, for example, 6 hours.

The state of charge “normal charging” (NORM) is characterized by an energy storage voltage that is higher than the threshold for fast charging. The NORM range is dimensioned, for example, between 3.7 V and 4.35 V. The charging operation in the NORM state of charge is intended to extend the lifespan of the energy storage device by reducing the charging current once the energy storage device is sufficiently charged for several hours of operation.

The state of charge “terminate charging” (TERM) is reached when the energy storage voltage is almost at the full charging specification, for example between 4.2 V and 4.35 V.

Among the four states of charge, the FAST state of charge has the highest charging current. This is followed by the charging current of the NORM state of charge, with the ODBR state of charge having the next highest current value. The TERM state of charge has the lowest charging current.

In one expedient embodiment, the charging voltage is adjusted to the specified voltage level when the state of charge changes. This means that the charging voltage is changed stepwise or incrementally in particular when a change in the state of charge—i.e., a transition between two defined or stored states of charge, or between two stored thresholds (threshold ranges)—is detected. With such a stepwise modification, voltage adjustments only occur during state-of-charge transitions and otherwise remain constant, whereas a continuous change, as in the prior art, requires continuous monitoring and adjustment of the charging voltage, since the energy storage voltage increases continuously during the charging operation. Therefore, the stepwise modification approach requires less computing power at a charger compared to the continuous change method. The reduced computational complexity thus enables a more cost-effective controller to be used in carrying out the method. What is more, energy consumption at the charger during the charging operation is advantageously reduced. In particular, the method according to the invention thus exhibits reduced complexity and higher reliability than does continuous adjustment of the charging voltage.

In this embodiment, the charging voltage is therefore only changed in response to significant fluctuations in the charging current flow without requiring any energy storage voltage information from the device. Therefore, the charging voltage is only adjusted during transitions between states of charge, for example from deep discharge (ODBR) to fast charging (FAST), from fast charging (FAST) to normal charging (NORM), and from normal charging (NORM) to termination of charging (TERM). These transitions are associated with significant changes in charging current intensity, which makes simple, reliable, and operationally safe detection of the state-of-charge transitions possible.

The stepwise variation of the charging voltage is a simplified form of the well-known continuous voltage variation in which the charging voltage is only adjusted when there is a significant change in the charging current. These changes in the current flow to the charge controller of the electronic device trigger the determination of the state of charge and regulate the charging voltage of the charger.

With the above and other objects in view there is provided, in accordance with the invention, a charger which is intended, suitable, and configured for charging a rechargeable energy storage device of an electronic device. For example, a portable charger has an energy source in the form of an integrated charging energy storage device and/or an energy interface (power connection, power supply, etc.) to provide electrical charging energy by means of which the energy storage device of the electronic device is charged during a charging operation. The energy source can be a rechargeable battery, for example, such as a power bank—i.e., an electrical device that can provide charging energy (e.g., a laptop or similar device that can also supply other electrical devices with energy via a USB port). The charger can also be a portable (rechargeable) battery module.

The charger also features a charging interface that can be connected to the electronic device for energy transfer. The charger also features a power converter (inverter, voltage transformer) that is coupled to the charging interface. The power converter is connected between the charging interface and the charging energy source (charging energy storage, energy interface, . . . ) and generates a charging voltage during charging for a charging operation based on the charging energy.

The charger also features a current sensor for detecting the charging current during a charging operation. In particular, the charger features a voltage-current sensor for monitoring the charging current and voltage at the charging interface and the output voltage at the power converter.

The voltage-current measurement and the power converter are coupled to a controller (i.e., a control unit). This results in an especially suitable charger. The voltage sensor is used to monitor the charging voltage and to provide feedback to the controller of the charger which is used in particular to regulate the charging voltage and output voltage of the power converter.

The controller is generally configured—in terms of programming and/or circuitry—to carry out the method according to the invention described above. The controller is thus specifically designed to set a constant nominal charging voltage of the power converter at the beginning of a charging operation and, during the charging operation, to subsequently determine a current state of charge of the device-side energy storage and a suitable voltage level for the same based on a measured charging current intensity, and to set the charging voltage to this voltage level.

In a preferred embodiment, the controller is embodied, at least in its core, by a microcontroller with a processor and a data storage in which the functionality for carrying out the method according to the invention is implemented programmatically in the form of operating software (firmware), so that the method—optionally in interaction with a device user—is carried out automatically when the operating software is executed in the microcontroller. Within the scope of the invention, the controller can also be alternatively instantiated by a non-programmable electronic component, such as an application-specific integrated circuit (ASIC) or an FPGA (Field Programmable Gate Array), in which the functionality for carrying out the method according to the invention is implemented using circuit technology. A circuit-based or hardware-based implementation of the controller using window comparators is also conceivable.

The measured voltage and current intensity levels are fed into the controller to determine and process the changing state of charge. This processing preferably forms a complete feedback loop in which the current state of charge is determined and the output voltage of the power converter is adjusted. In an advantageous embodiment, the adjustment of the output voltage of the power converter is controlled and/or regulated by varying a variable output signal of the controller. In other words, the controller generates an output signal for the power converter in order to adjust and regulate the output voltage thereof and to change the charging voltage so that it corresponds to the voltage level appropriate for the current state of charge.

The adjustment or modification of the output signal is achieved, for example, by pulse width modulation (PWM) or by digital-to-analog conversion (DAC). Changes to these output signals alter the output voltage of the power converter, which in turn adjusts the charging voltage supplied to the charging interface and the input of the device.

In a preferred embodiment, the charging voltage generated by the power converter is regulated by a control loop. This enables reliable and operationally safe variation of the output voltage. In particular, a closed-loop control system is provided for the power converter. The power converter either has an external, controlled system or is designed as an IC-based power converter with an integrated, controlled system.

The charging system according to the invention comprises a charger as described above and an electronic device with a rechargeable energy storage device. This results in an especially suitable charging system. In particular, reliable and efficient charging of the energy storage device is enabled without an additional communication link between the charger and the device.

In an expedient embodiment, the electronic device has a (device) charging interface for coupling to the charger and a charge controller that is coupled between the charging interface and the energy storage device.

Preferably, the electronic device is a hearing instrument or hearing device, in particular a personal sound amplification product.

Other features which are considered as characteristic for the invention are set forth in the appended claims.

Although the invention is illustrated and described herein as embodied in a method for charging a rechargeable energy storage device, a charger, and a charging system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a schematic representation of a charging system with a charger and an electronic device;

FIG. 2 shows a voltage-current-time diagram for a charging operation of the charging system;

FIG. 3 shows a flowchart of a method for carrying out the charging operation;

FIG. 4 shows a schematic representation of a current sensor of the charger;

FIG. 5 shows a schematic representation of a voltage sensor of the charger;

FIGS. 6 to 11 show schematic representations of various exemplary embodiments of a power converter of the charger;

FIG. 12 shows a schematic representation of a control loop for regulating an output voltage of the power converter;

FIGS. 13 and 14 show schematic representations of two exemplary embodiments of a switch-based power converter with integrated circuit;

FIG. 15 shows a schematic representation of a switch-based power converter with an integrated circuit;

FIG. 16 shows a schematic representation of a window comparator;

FIG. 17 shows a flowchart for a hardware-implemented method for carrying out the charging operation;

FIG. 18 shows a voltage-current-time diagram for a charging operation with constant charging voltage, and

FIG. 19 shows a voltage-current-time diagram for a charging operation with stepwise adjustment of the charging voltage;

FIG. 20 shows a power-time diagram for a charging operation with constant charging voltage and for a charging operation with stepwise adjustment of the charging voltage; and

FIG. 21 shows an efficiency-time diagram for a charging operation with constant charging voltage and for a charging operation with stepwise adjustment of the charging voltage.

Analogous parts and quantities are provided with the same reference numerals and symbols throughout the figures.

### DETAILED DESCRIPTION OF THE INVENTION

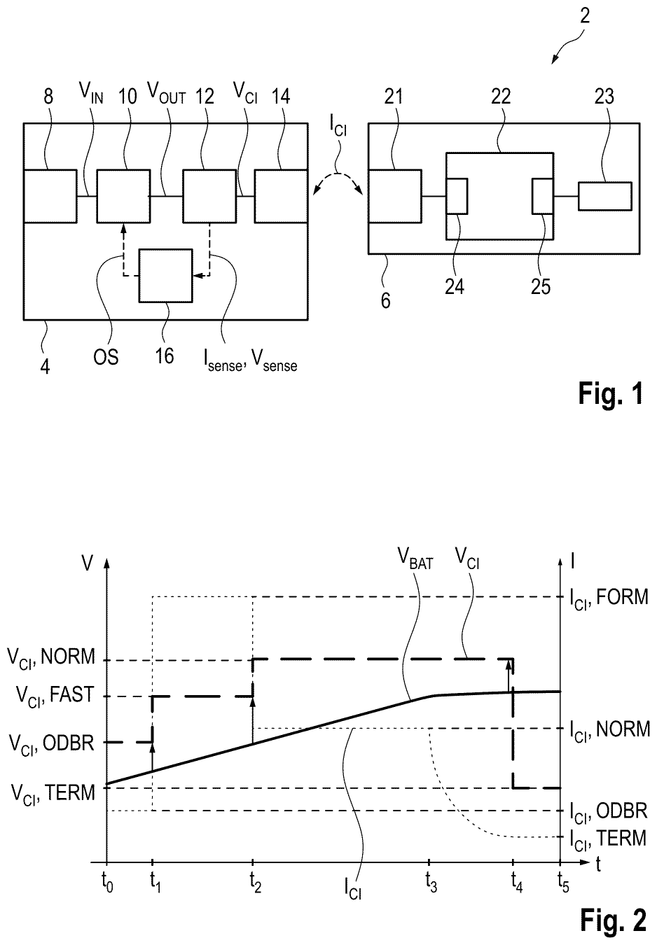

Referring now to the figures of the drawing in detail and first, in particular, to FIG. 1 thereof, there is shown a schematic and simplified representation of a charging system 2 with a charger 4 and an electronic device 6. The charging system 2 is implemented without a communication link or communication protocol between the charger 4 and the electronic device 6.

The charger 4 has a power source 8, a power converter 10 for providing a charging voltage V_{CI}, a current-voltage sensor (VI sensor) 12, a charging interface 14, and a controller 16.

The energy source 8 provides the electrical energy for a charging operation of the charger 4 and is embodied, for example, as an energy storage device that is integrated into the charger 4 and/or as an energy interface, in particular as a mains connection (power supply, power connection).

The power converter 10 converts an input voltage V_{IN} of the energy source 8 into an output voltage V_{OUT}, which is applied to the charging interface 14 as a charging voltage V_{CI}. The power converter 10 is particularly a converter or voltage transformer.

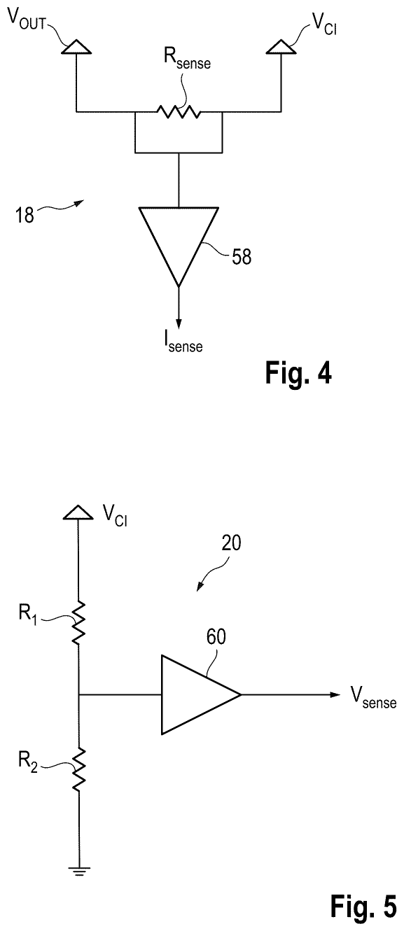

The current-voltage sensor 12 is embodied as a combined current sensor 18 (FIG. 4) and voltage sensor 20 (FIG. 5). In a charging mode of the charger 4 in which the device 6 is being charged, the current-voltage sensor 12 monitors a charging current I_{CI} as well as the charging voltage V_{CI} at the charging interface 14 and the output voltage V_{OUT}. The voltage sensor 20 is used during charging particularly for the purpose of monitoring the charging voltage V_{CI} in order to maintain it at a desired voltage level, while the current sensor 18 continuously monitors the charging current I_{CI}.

The charging interface 14 is embodied in particular as a charging contact or charging port (charging contact port) which is galvanically coupled to a (device) charging interface 21 of the electronic device 6 during a charging operation. The charging interfaces 14, 21 are embodied, for example, as a plug-socket pair for a plug connection.

The electronic device 6 has a charging interface 21, a charge controller 22, and an energy storage device 23 that can be recharged by the charger 4. The charge controller 22 has a charging input 24 that is connected to the charging interface 21 and a battery terminal 25 that is connected to the energy storage device 23. The energy storage device 23 is embodied in particular as a rechargeable battery, preferably as a lithium-ion battery. The electronic device 6 is embodied in particular as a hearing instrument, preferably as a personal sound amplification product, with a battery voltage V_{BAT} of the energy storage device 23 being dimensioned during operation of the electronic device 6 at between 3.0 V and 4.2 V, for example.

The controller 16 is coupled to the current-voltage sensor 12 and to the power converter 10 by signal technology. During charging, the current-voltage sensor 12 sends a measure of the measured current intensity Iₛₑₙₛₑ of the charging current I_{CI} and a measure of the measured voltage level Vₛₑₙₛₑ of the charging voltage V_{CI} to the controller 16. Based on the received sensor data, the controller 16 generates an output signal OS for controlling and/or regulating (closed-loop controlling) the power converter 10 or for controlling and/or regulating the output voltage V_{OUT}.

Owing to a certain amount of power consumption in the charge controller 24, the charging current I_{CI} flowing via the charging interfaces 14, 21 is dimensioned somewhat higher than the charging current associated with the respective state of charge. This relationship is illustrated in the following equation,

$${I}_{CI} = {I}_{B A T} + {I}_{OC}$$

where I_{BAT} denotes the charging current flowing to the energy storage device 23 and I_{OC} denotes the power consumption of the charge controller 24.

At the beginning of a charging operation, the controller 16 sets a constant nominal charging voltage V_{CI} or a constant nominal output voltage V_{OUT} of the power converter 10. The voltage level of this initial charging voltage V_{CI} is dimensioned such that the charge controller 24 of the electronic device 6 begins to operate. In other words, the resulting charging current I_{CI} is dimensioned to be greater than or equal to the power consumption I_{OC} of the charge controller 24.

During the charging operation, the electrical charging current I_{CI} flowing through the charging interface 14 is detected by means of the current sensor 18 and sent to the controller 16. The current intensity of the charging current I_{CI} depends on the state of charge of the device-side energy storage device 23, so that the measured current intensity Iₛₑₙₛₑ can be used to determine a current state of charge. The controller 16 is intended and configured to determine the current state of charge based on the measured current intensity Iₛₑₙₛₑ and to generate an output signal OS in order to adjust the charging voltage V_{CI} or the output voltage V_{OUT} so that a voltage level is provided which is suitable for the current state of charge.

For this purpose, for example, four states of charge of the energy storage device 23 are stored based on current thresholds or current threshold ranges stored in the controller 16 or implemented in the circuit.

In this example, four states of charge for the energy storage device are defined and stored. The states of charge include, for example, “over-discharged battery recovery” (ODBR), “fast charging” (FAST), “normal charging” (NORM) and “terminate charging operation” (TERM). The FAST state of charge has the highest charging current I_{CI, FAST} among the four states of charge. This is followed by the charging current I_{CI, NORM} of the NORM state of charge, with the ODBR state of charge having the next highest charging current W, ODBR. The TERM state of charge has the lowest charging current I_{CI, TERM}. During charging, the detected charging current Iₛₑₙₛₑ is compared with the charging current values for the states of charge, and a respectively suitable charging voltage V_{CI, FAST}, V_{CI, NORM}, V_{CI, ODBR}, V_{CI, TERM} is set on that basis.

Preferably, the charging voltage V_{CI} is modified in a stepwise manner in response to significant fluctuations in the detected current intensity Iₛₑₙₛₑ without transmission of information about the state of charge from the device 6 to the charger 4. Therefore, the charging voltage V_{CI} is only adjusted during transitions between states of charge, for example from deep discharge (ODBR) to fast charging (FAST), from fast charging (FAST) to normal charging (NORM), and from normal charging (NORM) to termination of charging (TERM). These transitions are associated with significant changes in the charging current intensity Iₛₑₙₛₑ, which makes simple, reliable, and operationally safe detection of the state-of-charge transitions possible.

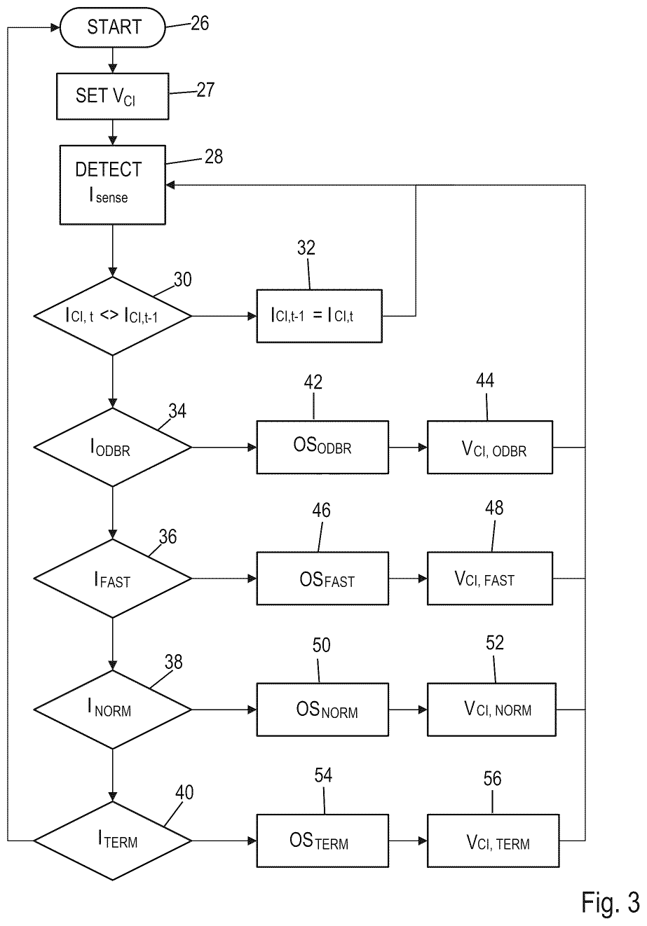

The charging method, or rather the stepwise variation of the charging voltage V_{CI}, is explained in greater detail below with reference to FIGS. 2 and 3.

FIG. 2 shows a schematic charging profile for a charging operation in a combined time-voltage and time-current diagram in which the energy storage device 23 is charged from a deeply discharged state of charge to a substantially fully charged state of charge. In FIG. 2, the time t is plotted horizontally, i.e., along the abscissa axis (X-axis), and the voltage V (left axis) and current intensity I (right axis) are plotted along the vertical ordinate axis (Y-axis). The time course of the battery voltage V_{BAT} is shown with a solid line, while the time course of the charging current I_{CI} is shown with dotted lines and the time course of the charging voltage V_{CI} is shown with dashed lines.

During the time period t₀ to t₁, there is an ODBR state of charge; during the time period t₁ to t₂, there is a FAST state of charge; during the time period t₂ to t₄, there is a NORM state of charge; and during the time period t₄ to t₅, there is a TERM state of charge.

The ODBR state of charge occurs when the battery voltage V_{BAT} is below a normal operating range, for example below 3.0 V. The ODBR state of charge enables recovery after a deep discharge of the energy storage device.

The FAST state of charge occurs when the battery voltage V_{BAT} is within a normal operating range but close to a lower end, for example between 3.0 V and 3.9 V.

The NORM state of charge is characterized by a battery voltage V_{BAT} which is higher than the threshold for fast charging. The NORM range is dimensioned, for example, between 3.7 V and 4.35 V.

The TERM state of charge “terminate charging operation” is reached when the energy storage voltage is almost at the full charging specification, for example between 4.2 V and 4.35 V. In FIG. 2, for example, the energy storage device 23 is almost fully charged at timepoint t₃, so that the charging current I_{CI} decreases and the TERM state of charge is initiated.

FIG. 3 shows a flowchart of the charging method. To better explain the method, the measured current intensity Iₛₑₙₛₑ is also referred to below as the charging current I_{CI} at a specific timepoint t with the notation I_{CI, t}. The controller 16 is specifically embodied as a microcontroller (MCU).

To carry out the charging method, the charging interfaces 14 and 21 are connected together, and the process is initiated with a method step 26.

In a subsequent method step 27, the charging voltage V_{CI} is set to a constant nominal charging voltage or to a constant nominal voltage level. For example, the charging current I_{CI, 0} is set to zero (I_{CI, 0}=). The voltage level is selected such that the charge controller 22 is activated.

During the method, in a method step 28, the current intensity Iₛₑₙₛₑ of the charging current I_{CI} is detected by the current-voltage sensor 12, so that the charging current I_{CI} is available to the controller 16 for evaluation at the respective timepoint t.

In a first threshold comparison 30, the controller 16 compares the currently measured charging current I_{CI, t} with the previously measured charging current I_{CI,t-1} at the timepoint t−1, taking into account a tolerance range. In other words, it is checked whether the currently measured charging current I_{CI,t} is greater than the difference between the previously measured charging current I_{CI,t-1} and a tolerance value Iₜₒₗ and whether the currently measured charging current I_{CI,t} is less than the sum between the previously measured charging current I_{CI,t-1} and the tolerance value Iₜₒₗ. The threshold comparison 30 is therefore given by the following formula:

$${I}_{CI , t - 1} - {I}_{tol} \leq {I}_{CI , t} \leq {I}_{CI , t - 1} + {I}_{tol}$$

In the case of a positive comparison result, the charging current I_{CI} has remained essentially constant, and the previous value is overwritten with the current measured value (I_{CI, t-1}=I_{CI, t}) in a method step 32.

A positive comparison result indicates a sufficiently large change in the charging current intensity; in other words, the charging current I_{CI, t} has changed significantly compared to the charging current I_{CI, t-1}. This means that the state of charge of energy storage 32 has changed significantly. In this case, the current charging current I_{CI, t} is compared with the stored threshold values for the states of charge ODBR, FAST, NORM, and TERM, each taking into account a tolerance range or the tolerance value Iₜₒₗ. Four threshold comparisons 34, 36, 38, 40 are carried out for this purpose. The threshold comparisons are performed, for example, in parallel or sequentially, for example in staggered fashion according to the magnitude of the respective charging currents (TERM, ODBR, NORM, FAST), or as shown in FIG. 3 according to an expected time sequence for a charging operation in which the energy storage device 23 is charged from a deeply discharged state of charge to a substantially fully charged state of charge.

In the threshold comparison 34, the controller 16 compares the currently measured charging current I_{CI, t} with the threshold for the ODBR charging current I_{CI, ODBR}, while taking a tolerance range into account. In other words, it is checked whether the currently measured charging current I_{CI,t} is greater than the difference between the threshold value for the ODBR charging current I_{CI, ODBR} and a tolerance value Iₜₒₗ, and whether the currently measured charging current I_{CI,t} is less than the sum between the threshold value for the ODBR charging current I_{CI, ODBR} and the tolerance value Iₜₒₗ. The threshold comparison 34 is therefore given by the following formula:

$${I}_{CI , ODBR} - {I}_{tol} \leq {I}_{CI , t} \leq {I}_{CI , ODBR} + {I}_{tol}$$

If the comparison result is positive, i.e., if the currently measured charging current I_{CI, t} essentially corresponds to the threshold value for the ODBR charging current I_{CI, ODBR}, the controller 16 generates an output signal OS ODBR (OS=OS_{ODBR}) in a method step 42 and sends it to the power converter 10. In a method step 44, the power converter 10 then regulates the charging voltage V_{CI} to the appropriate charging voltage V_{CI, ODBR} for the “over-discharged battery recovery” state of charge (V_{CI}=V_{CI, ODBR}). The resulting charging current is then measured in method step 28.

In the event of a negative comparison result, i.e., if the currently measured charging current I_{CI, t} is not within the tolerance range of the ODBR charging current I_{CI, ODBR}, the threshold comparison 36 is performed.

In the threshold comparison 36, the controller 16 compares the currently measured charging current I_{CI, t} with the threshold for the FAST charging current I_{CI, FAST}, while taking a tolerance range into account. In other words, it is checked whether the currently measured charging current I_{CI,t} is greater than the difference between the threshold value for the FAST charging current I_{CI, FAST} and a tolerance value Iₜₒₗ, and whether the currently measured charging current I_{CI,t} is less than the sum between the threshold value for the FAST charging current I_{CI, FAST} and the tolerance value Iₜₒₗ. The threshold comparison 36 is therefore given by the following formula:

$${I}_{CI , FAST} - {I}_{tol} \leq {I}_{CI , t} \leq {I}_{CI , FAST} + {I}_{tol}$$

If the comparison result is positive, i.e., if the currently measured charging current I_{CI, t} essentially corresponds to the threshold value for the FAST charging current I_{CI, FAST}, the controller 16 generates an output signal OS FAST (OS=OS_{FAST}) in a method step 46 and sends it to the power converter 10. The power converter 10 then regulates the charging voltage V_{CI} to the appropriate charging voltage V_{CI, FAST} for the “fast charging” state of charge (V_{CI}=V_{CI, FAST}) in a method step 48. The resulting charging current is then measured in method step 28.

In the event of a negative comparison result, i.e., if the currently measured charging current I_{CI, t} is not within the tolerance range of the FAST charging current I_{CI, FAST}, the threshold comparison 38 is performed.

In the threshold comparison 38, the controller 16 compares the currently measured charging current I_{CI, t} with the threshold for the NORM charging current I_{CI, NORM}, while taking a tolerance range into account. In other words, it is checked whether the currently measured charging current I_{CI,t} is greater than the difference between the threshold value for the NORM charging current I_{CI, NORM} and a tolerance value Iₜₒₗ, and whether the currently measured charging current I_{CI,t} is less than the sum between the threshold value for the NORM charging current I_{CI, NORM} and the tolerance value Iₜₒₗ. The threshold comparison 38 is therefore given by the following formula:

$${I}_{CI , NORM} - {I}_{tol} \leq {I}_{CI , t} \leq {I}_{CI , NORM} + {I}_{tol}$$

If the comparison result is positive, i.e., if the currently measured charging current I_{CI, t} essentially corresponds to the threshold value for the NORM charging current I_{CI, NORM}, the controller 16 generates an output signal OS NORM (OS=OS_{NORM}) in a method step 50 and sends it to the power converter 10. The power converter 10 then regulates the charging voltage V_{CI} to the appropriate charging voltage V_{CI, NORM} for the “normal charging” state of charge (V_{CI}=V_{CI, NORM}) in a method step 52. The resulting charging current is then measured in method step 28.

In the event of a negative comparison result, i.e., if the currently measured charging current I_{CI, t} is not within the tolerance range of the NORM charging current I_{CI, NORM}, the threshold comparison 40 is performed.

In the threshold comparison 40, the controller 16 compares the currently measured charging current I_{CI, t} with the threshold for the TERM charging current I_{CI, TERM}, while taking a tolerance range into account. In other words, it is checked whether the currently measured charging current I_{CI,t} is greater than the difference between the threshold value for the TERM charging current I_{CI, TERM} and a tolerance value Iₜₒₗ, and whether the currently measured charging current I_{CI,t} is less than the sum between the threshold value for the TERM charging current I_{CI, TERM} and the tolerance value Iₜₒₗ. The threshold comparison 40 is therefore given by the following formula:

$${I}_{CI , TERM} - {I}_{tol} \leq {I}_{CI , t} \leq {I}_{CI , TERM} + {I}_{tol}$$

If the comparison result is positive, i.e., if the currently measured charging current I_{CI, t} essentially corresponds to the threshold value for the TERM charging current I_{CI, TERM}, the controller 16 generates an output signal OS TERM (OS=OS_{TERM}) in a method step 54 and sends it to the power converter 10. The power converter 10 then regulates the charging voltage V_{CI} to the appropriate charging voltage V_{CI, TERM} for the “terminate charging operation” state of charge (V_{CI}=V_{CI, TERM}) in a method step 56. The resulting charging current is then measured in method step 28.

In the event of a negative comparison result, i.e., if the currently measured charging current I_{CI,t} is not within the tolerance range of the TERM charging current I_{CI, TERM}, the charging current I_{CI, t} is essentially outside the tolerance ranges of the stored states of charge ODBR, FAST, NORM, TERM, and method step 28 is initiated.

The tolerance ranges for the threshold comparisons 34, 36, 38, 40 enable the charging voltage V_{CI} to be adjusted stepwise or incrementally when a change in the state of charge—i.e., a transition between two defined or stored states of charge, or between two stored thresholds (threshold ranges)—is detected. With such a stepwise modification, voltage adjustments only occur during state-of-charge transitions and otherwise remain constant (FIG. 2).

FIG. 4 shows an embodiment of the current sensor 18 which is implemented with a series resistor Rₛₑₙₛₑ in conjunction with an amplifier circuit 58. The input of the amplifier 58 is derived from the voltage drop across the series resistor Rₛₑₙₛₑ, which creates a potential difference when current flows through it. The amplifier 58 then amplifies this voltage drop to a higher level and sends the output signal as a current measurement level Iₛₑₙₛₑ in the voltage range to an analog-to-digital converter (ADC) input of the controller 16. For example, the controller 16 uses an algorithm to convert the ADC voltage input into a digital representation of the actual charging current I_{CI}. The series resistor Rₛₑₙₛₑ is selected so as to have the lowest possible resistance value in order to minimize power losses and voltage drops and thereby maintain the output voltage V_{OUT} of the power converter 10 close to the charging voltage V_{CI} of the charging interface 14. Preferably, the series resistor Rₛₑₙₛₑ has a value of less than 1Ω (Ohm). Preferably, an amplifier 58 with the highest possible gain is used to compensate for the low resistance of the series resistor Rₛₑₙₛₑ and to improve the resolution of the detected current level which is suitable for the ADC of the controller 16. Advantageously, the amplifier circuit 58 is implemented using a differential operational amplifier with a gain value of more than 10.

The voltage sensor 10 shown in FIG. 5 is implemented, for example, using a voltage divider connected to an amplifier circuit 60. The input of amplifier 60 is connected to the output of the voltage divider, which is located between two resistors R₁, R₂. The voltage divider reduces the voltage at the charging interface 14 to a lower voltage level. The amplifier 60 then follows this input voltage level and outputs it to a corresponding ADC port of the controller 16 as a voltage measurement level Vₛₑₙₛₑ. The controller 16 converts this voltage measurement Vₛₑₙₛₑ into a digital value which reflects the actual charging voltage V_{CI} measured at the charging interface 14 for further processing. The voltage divider reduces the charging voltage V_{CI} of the charging interface 14 of the charger 4 to a voltage level that is appropriate for the ADC input range of the controller 16. Preferably, high resistance values are selected for both resistors R₁, R₂ in the voltage divider in order to minimize the current flow through the voltage divider circuit during the voltage measurement. The amplifier circuit 60 can be implemented, for example, with a voltage follower which maintains the same voltage level at the input and output while drawing a negligible current to and from the ADC input of the controller 16.

The measured voltage and current levels Iₛₑₙₛₑ, Vₛₑₙₛₑ are fed into the ADC port of the controller 16 to determine and process the changing state of charge. This processing preferably forms a complete feedback loop in which the current state of charge is determined and the output voltage V_{OUT} of the power converter 10 is adjusted. The adjustment of the output voltage V_{OUT} of the power converter 10 is controlled and/or regulated by varying the output signal OS of the controller 16. In other words, the controller 16 generates an output signal OS for the power converter 10 in order to adjust and regulate the output voltage V_{OUT} thereof and to change the charging voltage V_{CI} so that it corresponds to the voltage level that is suitable for the current state of charge.

The adjustment or modification of the output signal OS is achieved, for example, by pulse width modulation (PWM) or by digital-to-analog conversion (DAC). Changes to these output signals OS alter the output voltage V_{OUT} of the power converter 10, which in turn adjusts the charging voltage V_{CI} supplied to the charging interface 14 and the input of the device 6.

In the hardware implementation shown in FIG. 1, the power converter 10 is crucial for adjusting the charging voltage V_{CI} by converting the output voltage V_{OUT}. For example, the charger 4 has a power source 8 in the form of a USB port which provides a constant input voltage V_{IN} of 5 V, while the operating voltage range for lithium-ion batteries is normally between 3.0 V and 4.2 V. Therefore, the power converter 10, which maintains a common ground between input and output, can have different topologies.

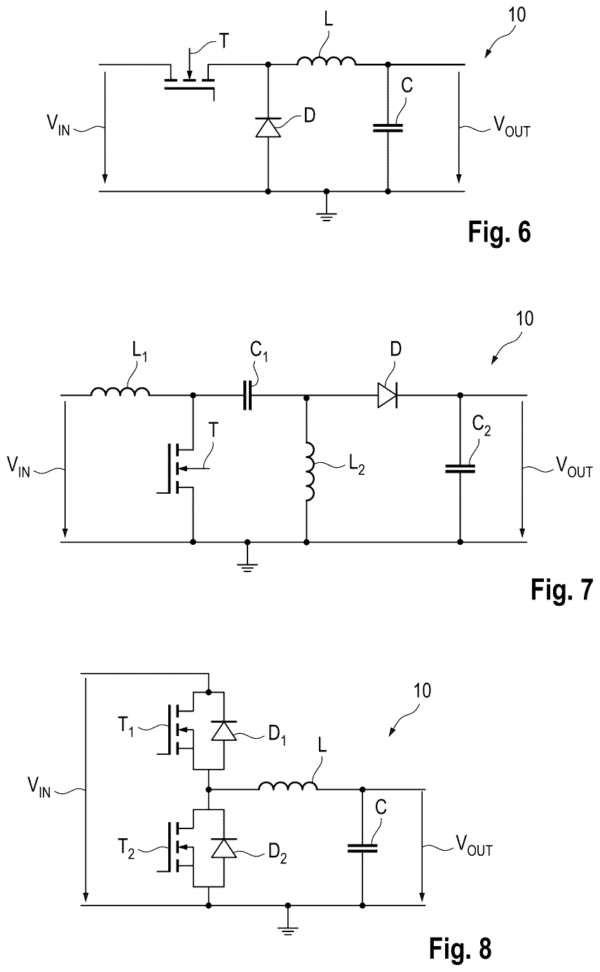

FIG. 6 shows an embodiment of the power converter 10 as a buck converter. The power converter 10 has a transistor T, an inductor L, a (freewheeling) diode D, and an (output) capacitor C, which are connected in a buck converter circuit familiar to those skilled in the art. The buck converter is designed to reduce the output voltage V_{OUT} compared to the input voltage V_{IN}.

FIG. 7 shows an embodiment of the power converter 10 as a SEPIC converter, which can either increase or decrease the output voltage V_{OUT} compared to the input voltage V_{IN}. Both buck and SEPIC converters have a common ground between their input and output terminals.

The power converter 10 comprises two inductors L₁, L₂, a transistor T, two capacitors C₁, C₂, and a diode D, which are connected in a SEPIC converter circuit familiar to those skilled in the art.

FIG. 8 shows a power converter 10 that is embodied as a half-bridge buck converter comprising two transistors T₁, T₂ with body diodes D₁, D₂, an inductor L, and a capacitor C.

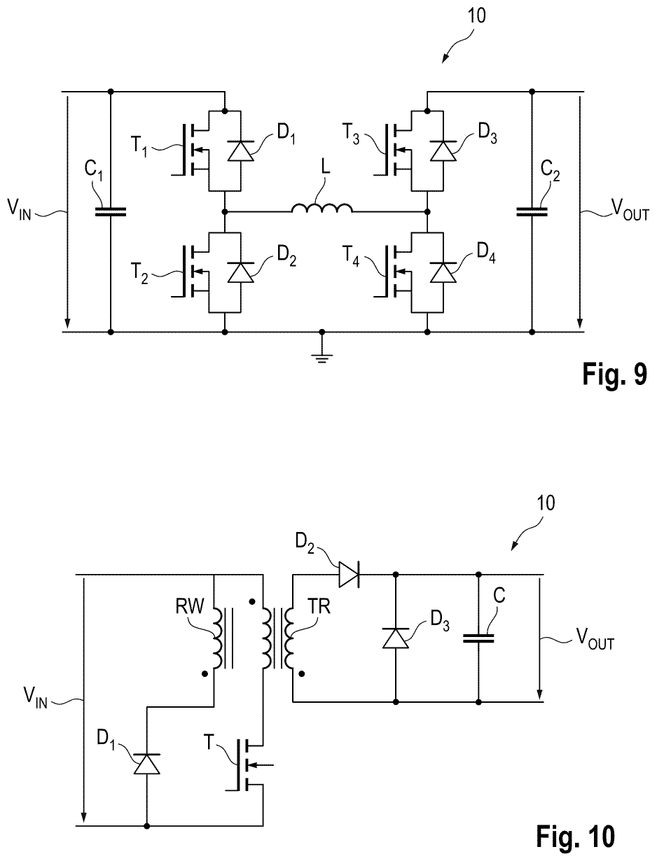

FIG. 9 shows an embodiment of the power converter 10 as a cascaded buck-boost converter comprising four transistors T₁, T₂, T₃, T₄ connected as two bridge branches with body diodes D₁, D₂, D₃, D₄, an inductor L connected between the bridge branches, and a capacitor C₁, C₂ connected in parallel to each of the bridge branches.

FIG. 10 shows a power converter 10 which is embodied as a forward converter for transformer-based current/voltage conversion. The power converter 10 has three diodes D₁, D₂, D₃, a transistor T, a transformer TR with reverse winding RW, and a capacitor C.

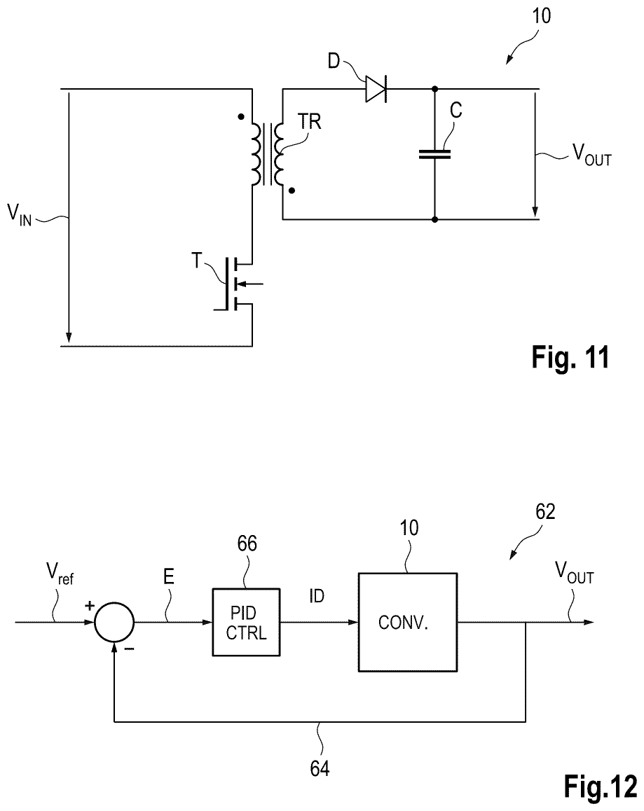

FIG. 11 shows a power converter 10 which is embodied as a flyback converter and is also designed for transformer-based current/voltage conversion. The power converter 10 has a diode D, a transistor T, a transformer TR, and a capacitor C.

A closed control loop system 62 is provided for varying the output voltage V_{OUT}. The control loop system 62 shown in FIG. 12 has a feedback loop as the control loop 64, which returns the output voltage V_{OUT} for comparison with a reference voltage V_{ref}. The reference voltage V_{ref} corresponds to the respective intended charging voltage V_{CI, FAST}, V_{CI, NORM}, V_{CI, ODBR}, V_{CI, TERM} for a current state of charge (FAST, NORM, ODBR, TERM), which is set or selected by the output signal OS of the controller 16.

A difference between the output voltage V_{OUT} and the reference voltage V_{ref} generates an error signal E. This error signal E is fed, for example, into a PID (proportional-integral-differential) controller 66, which continuously adjusts the output to correct deviations between the output voltage V_{OUT} and the set reference voltage V_{ref}. The PID controller 66 generates a duty cycle by comparing the error signal E with a periodic waveform, e.g., a sawtooth wave. This duty cycle is represented, for example, as a pulse width modulation (PWM) signal. The PWM signal is then amplified by a switching driver in order to control the switches of the power converter 10 and to turn them on and off. When the PWM signal changes, the inductor and capacitor in the power converter 10 are charged and discharged, thereby adjusting the output voltage V_{OUT} to the reference voltage V_{ref}.

The entire closed-loop control system 62, with the exception of the power converter 10, can also be implemented in the controller 16, for example. The output voltage V_{OUT} from the control loop 64 is sent via the voltage sensor 20 to an ADC of the controller 16. The controller 16 generates a PWM signal as an output signal OS to control the switch of the power converter 10 and generates, in conjunction with an external switching driver, a periodic duty cycle for regulating the power converter 10. The reference voltages V_{ref} are the voltage levels V_{CI, FAST}, V_{CI, NORM}, V_{CI, ODBR}, V_{CI, TERM} for each state of charge (FAST, NORM, ODBR, TERM) and are digitally stored or preset in a storage of the controller 16 and are adjusted based on the detected charging current I_{CI}.

Alternatively, a hardware approach to implementing a closed control loop is also possible. The reference voltage V_{ref} can be provided by a voltage divider or a low dropout (LDO) circuit. The error signal E is generated in particular by a differential amplifier circuit which compares the reference voltage V_{ref} with the output voltage V_{OUT} of the power converter 10. The duty cycle is achieved, for example, by a comparator, which receives the input of a periodic waveform and the output of a PID amplifier. The PID amplifier has a parallel proportional amplifier circuit, an integral amplifier circuit, and a differential amplifier circuit. The PID amplifier processes the error signal E, which is the output of the differential amplifier. The resulting duty cycle output signal is then sent to a switch driver, which amplifies the signal to a sufficient power level in order to control the switches in the power converter 10 and turn them on and off.

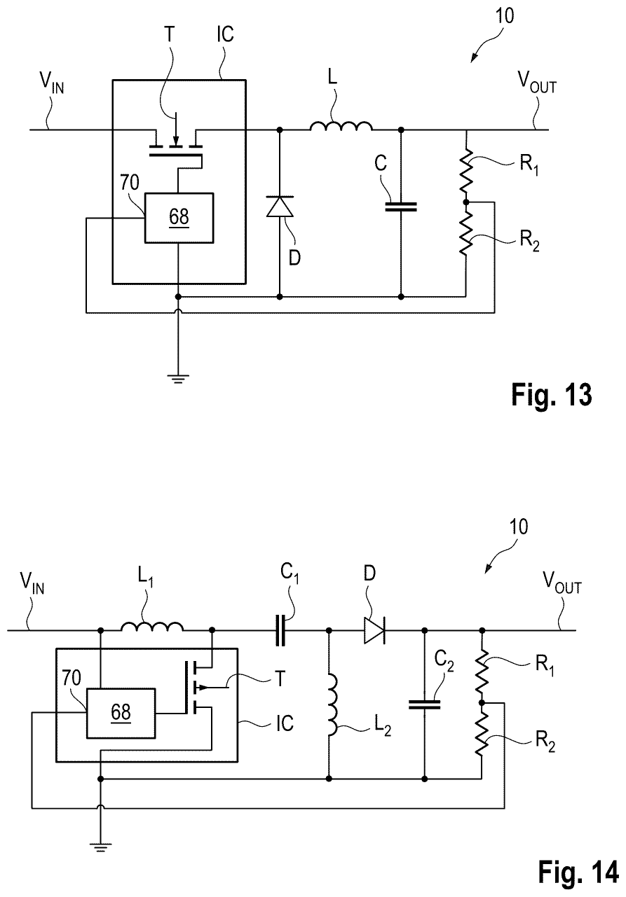

The closed-loop control system can also be implemented with an integrated circuit (IC) with a switch-based power converter, for example as an IC switch-based buck converter shown in FIG. 13 or as an IC switch-based SEPIC converter shown in FIG. 14. The control is integrated into a feedback control block 68 of the integrated circuit IC, which comprises functions such as comparator, PID controller, PWM generator, switching driver, soft start reference, current sensor, overcurrent protection, and oscillator. The integrated circuit IC contains a switch or transistor T which is controlled by a PWM generator and driver within the feedback control block 68.

A feedback pin 70 of the integrated circuit IC is used to regulate the output voltage V_{OUT} to ensure that it corresponds to the specified setpoint or reference voltage V_{ref}. The output voltage V_{OUT} is set by the ratio of two resistors R₁, R₂ connected in series and in parallel to the output of the power converter 10. The relationship between the output voltage V_{OUT}, of the resistors R₁, R₂ and the reference voltage V_{ref} is described by the following equation, which is derived from a voltage divider:

$${V}_{out} = ( \frac{R 1}{R 2} + 1 ) \times {V}_{r e f} .$$

In the embodiment shown in FIG. 13, the integrated circuit IC with circuit-based power converter further comprises a diode D, an inductor L, and a capacitor C, whereas in the variant shown in FIG. 14, a diode D, two inductors L₁, L₂, and two capacitors C₁, C₂ are provided.

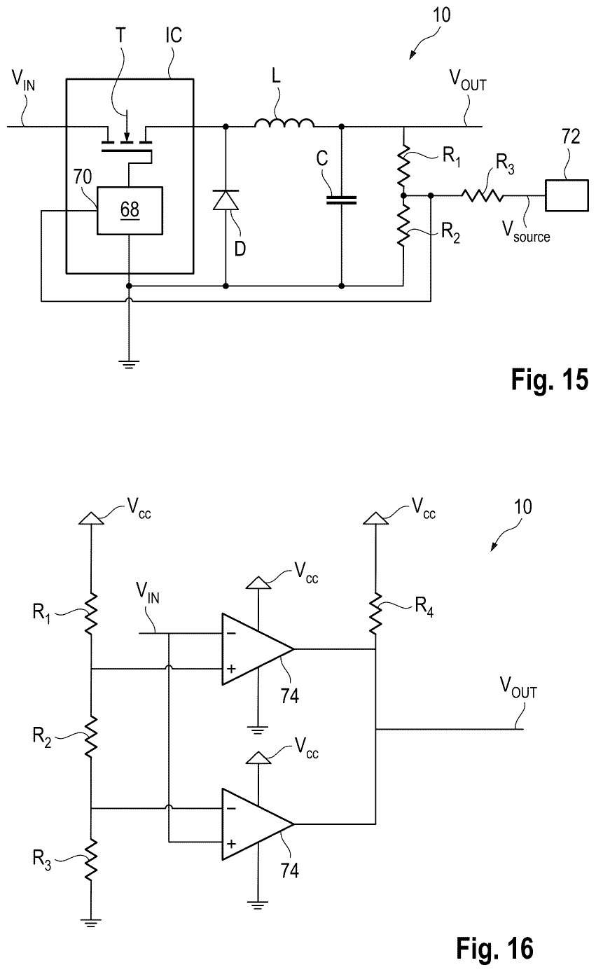

To adjust the output voltage V_{OUT} of an IC switch-based power converter 10, an additional circuit consisting of a voltage source 72 and a series resistor R₃ is introduced (FIG. 15). The output of this voltage source 72 with series resistor R₃ is connected to the output of the voltage divider and is fed into the feedback pin 70. The variation of the output voltage V_{OUT} is achieved by changing a voltage level Vsource of the voltage source 72. This adjustment can be achieved by modifying the pulse width modulation (PWM) signal from the controller 16 in conjunction with a low-pass filter. Alternatively, the level Vsource of the voltage source 72 can be varied by adjusting the output voltage of a digital-to-analog converter (DAC) within the controller 16. FIG. 15 illustrates the construction of the voltage source 72 and the series resistor R₃ in order to achieve a variable output voltage V_{OUT} using the example of a buck converter based on an IC circuit (FIG. 13). The output voltage V_{OUT} for the power converter 10 based on an integrated circuit IC is set by changing the voltage level Vsource, and the relationship between the output voltage V_{OUT} and the voltage level Vsource is given by the equation derived from a node analysis:

$${V}_{o u t} = ( \frac{{R}_{2} {R}_{3} + {R}_{1} {R}_{3} + {R}_{1} {R}_{2}}{{R}_{2} {R}_{3}} ) {V}_{ref} - ( \frac{{R}_{1}}{{R}_{3}} ) {V}_{source}$$

In addition to the algorithmic approaches shown in FIG. 1 and FIG. 3 for varying the output voltage V_{OUT} of IC switch-based power converters 10, an alternative solution is to use a window comparator circuit as shown in FIG. 16. The window comparator works by raising the output voltage V_{OUT} when both the upper and lower comparator 74 are in the high state. If either the upper or the lower comparator 74 (or both) is in the low state, V_{OUT} is lowered. The values of resistors R₁, R₂ and R₃ determine the input voltage range for the window comparator, which results in a high output voltage V_{OUT}. The relationship between the output voltage, the input voltage V_{IN}, the resistors R₁, R₂, R₃, and a supply voltage Vcc of the comparators 74 is described by the following equation:

$${V}_{out} = \{ \begin{matrix}{V}_{cc} : & \frac{{R}_{3}}{{R}_{1} + {R}_{2} + {R}_{3}} \leq {V}_{i n} \leq \frac{{R}_{2} + {R}_{3}}{{R}_{1} + {R}_{2} + {R}_{3}} \\ 0 : & {V}_{i n} < \frac{{R}_{3}}{{R}_{1} + {R}_{2} + {R}_{3}} or {V}_{i n} > \frac{{R}_{2} + {R}_{3}}{{R}_{1} + {R}_{2} + {R}_{3}}\end{matrix}$$

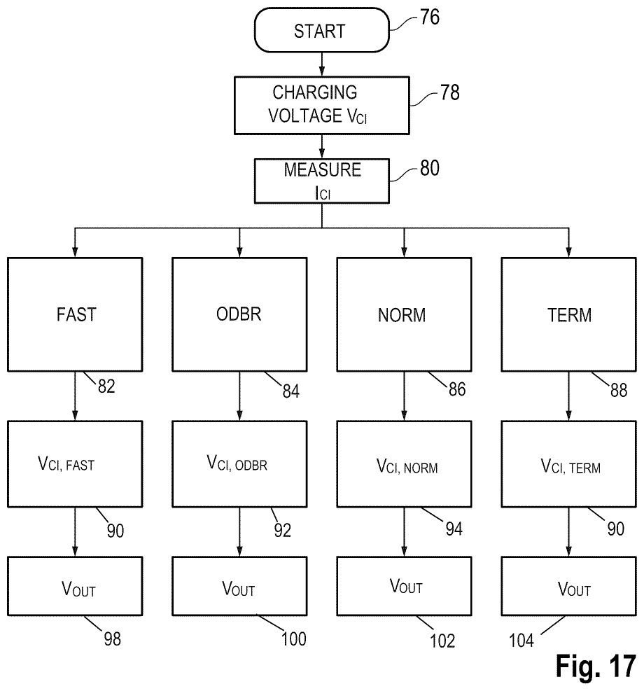

FIG. 17 illustrates the hardware approach for implementing a stepwise variation of the charging voltage V_{CI}, thereby achieving a similar function to the controller algorithm approach.

The charging method is initiated in a method step 76. First, in a method step 78, a constant nominal charging voltage V_{CI} is applied to the charging interface 14 in order to ensure that the charging operation starts correctly.

In a subsequent method step 80, the charging current I_{CI} is measured. The current flow is measured, for example, with the current sensor 18 shown in FIG. 4, converted into a voltage level and fed into a window comparator as input voltage V_{IN} in a method step 82, 84, 86, 88. In particular, four window comparators are provided, one for each intended state of charge (ODBR, FAST, NORM, TERM).

When the voltage level falls into one of the four preset voltage windows (FAST, ODBR, NORM, TERM), the output of the respective associated window comparator is raised. This high output activates a voltage source for the IC switch-based power converter 10 in a respective method step 90, 92, 94, 96 or provides a respective reference voltage V_{ref} (V_{CI, FAST}, V_{CI, NORM}, V_{CI, ODBR}, V_{CI}, TERM) for the closed system of the hardware approach. This voltage source typically comes from an LDO circuit or a voltage divider circuit. Finally, in each method step 98, 100, 102, 104, the power converter 10 adjusts its output voltage V_{OUT}, which is connected to the charging interface 14, in order to achieve the stepwise variation of the charging input voltage V_{CI}.

For the ODBR state of charge, method steps 82, 90, and 98 (V_{CI}=V_{CI, ODBR}) are executed; for the FAST state of charge, method steps 84, 92, and 100 (V_{CI}=V_{CI, FAST}) are executed; for the NORM state of charge, method steps 86, 94, and 102 (V_{CI}=V_{CI, NORM}) are executed; and for the TERM state of charge, method steps 88, 96, and 104 (V_{CI}=V_{CI, TERM}) are executed.

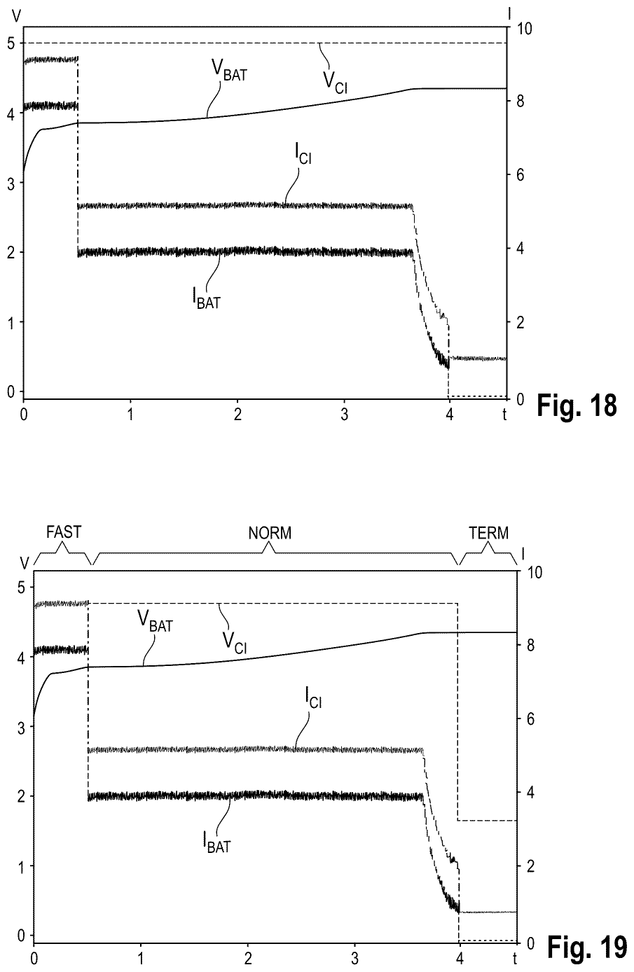

The following is an experimental comparison for a complete charging of the energy storage device 23 shown with reference to FIGS. 18 to 21, in which a conventional approach with constant charging voltage V_{CI} is compared with the inventive method with stepwise variation of the charging voltage V_{CI}.

FIGS. 18 and 19 show, in a combined time-voltage and time-current diagram, a schematic charging profile for a charging operation in which the energy storage device 23 is charged from a deeply discharged state of charge with a constant charging voltage V_{CI} (FIG. 18) and with a stepwise variation of the charging voltage V_{CI} (FIG. 19) to a substantially fully charged state of charge. In FIG. 18 and FIG. 19, the time t in hours (h) is plotted horizontally, i.e., along the abscissa axis (X-axis), and a voltage V in volts (V) (left axis) and a current intensity I in milliamperes (mA) (right axis) are plotted along the vertical ordinate axis (Y-axis).

The time course of the battery voltage V_{BAT} is shown with a solid line, while the time course of the charging voltage V_{CI} is shown with dashed lines. The time course of the charging current I_{CI} at the charging interface 14 is shown with a dash, and the time course of the battery current I_{BAT} fed into the energy storage device 23 by the charge controller 22 is shown with a dotted line.

In both charging methods, the same device 6 was tested under normal battery operation, with the battery voltage V_{BAT} between 3.0 V and 4.2 V. FIG. 18 shows the complete charging profile for the approach with constant charging voltage V_{CI}, while FIG. 19 shows the complete charging profile for the approach with stepwise variation of the charging voltage V_{CI}. The main difference between the two charging methods lies in the charging voltage V_{CI}. In the approach with stepwise modification of the charging voltage V_{CI}, the charging voltage V_{CI} is adjusted according to the mode or state of charge (FAST, NORM, TERM), while in the approach with constant charging voltage V_{CI} a fixed voltage supply is maintained throughout the entire charging operation.

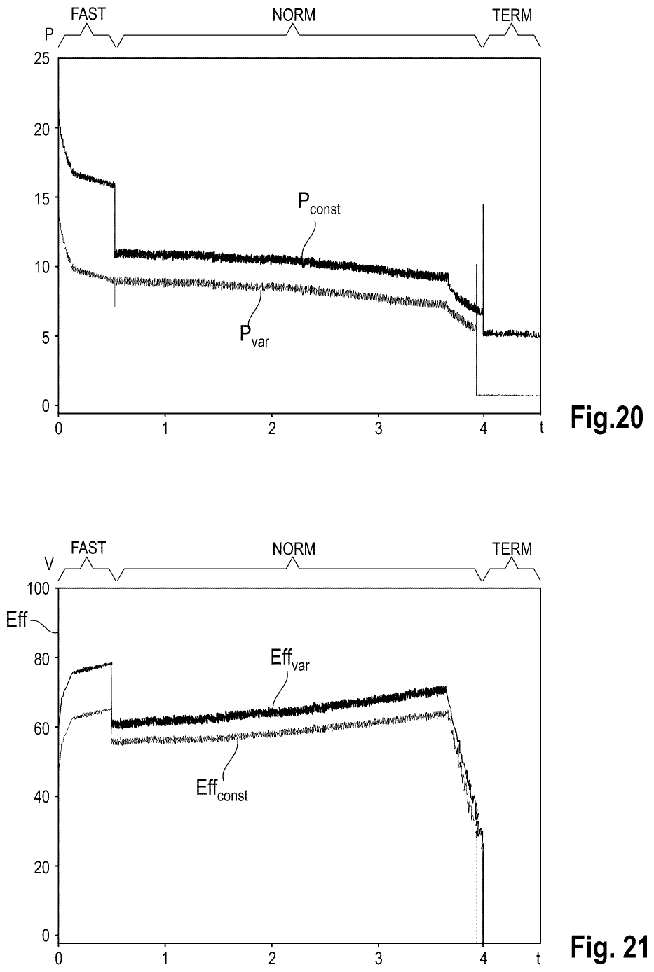

FIG. 20 shows a time-power diagram for the charging operations. In FIG. 20, the time t in hours (h) is plotted horizontally, i.e., along the abscissa axis (X-axis), and the power consumption P in milliwatts (mW) is plotted along the vertical ordinate axis (Y-axis). FIG. 20 illustrates the power profiles P_{const}, Pᵥₐᵣ both for the approach with constant charging voltage V_{CI} (P const) and the approach with stepwise variation of the charging voltage V_{CI} (P var). As can be seen relatively clearly in FIG. 20, the average power consumption is reduced by approximately 6 mW during fast charging (FAST) and by approximately 2 mW during normal charging (NORM) when the approach with stepwise modification is used. This reduction in power consumption suggests that the use of the stepwise modification of the charging voltage V_{CI} approach makes a more compact portable charger 6 and a higher number of charging cycles possible.

FIG. 21 shows a time-efficiency diagram for the charging operations. In FIG. 21, the time t in hours (h) is plotted horizontally, i.e., along the abscissa axis (X-axis), and the efficiency Eff in percent (%) is plotted along the vertical ordinate axis (Y-axis). FIG. 21 shows the (charging) efficiency profiles Eff_{const}, Effᵥₐᵣ for the entire charging operation, from the energy source 8 to the battery terminal 25, and compares the approach with constant charging voltage at the input (Eff_{const}) with the approach with stepwise variation of the charging voltage at the input (Effᵥₐᵣ). The stepwise modification approach shows a general improvement in charging efficiency of about 10% in fast charging (FAST) and about 5% in normal charging (NORM) compared to the constant charging voltage approach. However, in the final state of charge (TERM), the charging efficiency is similar for both methods, since the charging current I_{CI} to the energy storage 23 is very low.

It will be understood that the claimed invention is not limited to the exemplary embodiments described above. Rather, other variants of the invention may also be derived therefrom by a person skilled in the art within the scope of the disclosed claims, without departing from the subject matter of the claimed invention. In particular, all the individual features described in connection with the various exemplary embodiments can also be combined in other ways within the scope of the disclosed claims, without departing from the subject matter of the claimed invention.

The following are summary lists of reference numerals, symbols, and the corresponding structure used in the above description of the invention:
2 charging system
4 charger
6 device
8 energy source
10 power converter
12 current-voltage sensor
14 charging interface
16 controller
18 current sensor
20 voltage sensor
21 charging interface
22 charge controller
23 energy storage device
24 charging input
25 battery terminal
26, 27, 28 method step
30 threshold comparison
32 method step
34, . . . , 40 threshold comparison
42, . . . , 56 method step
58 amplifier circuit
60 amplifier circuit
62 control loop system
64 control loop, feedback loop
66 PID controller
68 feedback control block
70 feedback pin
72 voltage source
74 comparator
76, . . . , 104 method step
V_{CI} charging voltage
FAST, ODBR, TERM, NORM state of charge
V_{CI, FAST}, V_{CI,NORM}, charging voltage
V_{CI,ODBR}, V_{CI,TERM} charging voltage
V_{IN} input voltage
V_{OUT} output voltage
I_{CI} charging current
I_{CI, FAST}, I_{CI, NORM}, charging current
I_{CI, ODBR}, I_{CI, TERM} charging current
V_{BAT} battery voltage
I_{BAT} battery power
Iₛₑₙₛₑ current intensity
Vₛₑₙₛₑ voltage level
V voltage
current intensity
t time
Rₛₑₙₛₑ series resistor
R₁, R₂ resistor
T, T₁, T₂ transistor
L, L₁, L₂ inductance
D, D₁, D₂, D₃ diode
C, C₁, C₂ capacitor
t₀, t₁, t₂, t₃, t₄, t₅ timepoint
TR transformer
RW reverse winding
V_{ref} reference voltage
E error signal
V source voltage level
P power consumption
P_{const}, Pᵥₐᵣ performance profile
Eff efficiency
Eff_{const}, Effᵥₐᵣ efficiency profile

1. A method for charging a rechargeable energy storage device of an electronic device via a charging interface, the method comprising:
at a beginning of a charging operation, applying a stored charging voltage to the charging interface;
detecting a charging current flowing through the charging interface during the charging operation;
determining a current state of charge of the energy storage device based on the detected charging current;
determining a specific voltage level for the charging voltage for the state of charge; and
setting the charging voltage to the determined specific voltage level.

2. The method according to claim 1, which comprises determining the current state of charge by comparing the detected charging current with a stored current threshold.

3. The method according to claim 2, wherein a number of respective current thresholds are stored for different states of charge, and wherein the current state of charge is determined by comparing the detected charging current with the current thresholds.

4. The method according to claim 1, which comprises setting the charging voltage to the determined voltage level upon detecting a change in the state of charge.

5. A charger for charging a rechargeable energy storage device of an electronic device, the charger comprising:
a charging interface to be coupled to the electronic device for energy transfer;
a power converter connected to said charging interface for generating a charging voltage;
a current sensor for detecting a charging current; and
a controller for carrying out the method according to claim 1.

6. The charging device according to claim 5, wherein said controller is configured to control or to regulate said power converter by way of a variable output signal.

7. The charging device according to claim 5, wherein the charging voltage generated by said power converter is regulated by closed-loop control through a control loop.

8. A charging system, comprising a charger according to claim 5 and an electronic device with a rechargeable energy storage device.

9. The charging system according to claim 8, wherein said electronic device has a charging interface for coupling to said charger and a charge controller connected between said charging interface and said energy storage device.

10. The charging system according to claim 8, wherein said electronic device is a hearing device.

11. The charging system according to claim 10, wherein said hearing device is a personal sound amplification product.
